(19) United States
(12) Patent Application Publication
(10) Pub. No.: US 2025/0079325 A1
(43) Pub. Date: Mar. 6, 2025

(54) SEMICONDUCTOR DEVICE

(71) Applicant: SHINKO ELECTRIC INDUSTRIES CO., LTD., Nagano (JP)

(72) Inventor: Yoichi NISHIHARA, Nagano (JP)

(21) Appl. No.: 18/822,938

(22) Filed: Sep. 3, 2024

(30) Foreign Application Priority Data
Sep. 5, 2023 (JP) 2023-143597

(51) Int. Cl. H01L 23/538; H01L 23/00; H01L 23/31; H01L 25/065

(52) U.S. Cl. CPC H01L 23/5386; H01L 23/3107; H01L 23/5384; H01L 24/32; H01L 24/33; H01L 25/0655; H01L 2224/32225; H01L 2224/33181; H01L 2225/065

(57) ABSTRACT

A semiconductor device includes a wiring substrate and a semiconductor element. The wiring substrate includes an insulating layer and a wiring layer. The semiconductor element includes a first electrode and is fixed to the wiring substrate with the first electrode facing the wiring substrate. The wiring layer includes a first wiring pattern on a surface of the insulating layer on the opposite side from the semiconductor element. The wiring layer further includes a first via interconnect. The first via interconnect is formed of a sintering material of metal and fills in a first through hole piercing through the first wiring pattern and the insulating layer to expose the first electrode. The first via interconnect electrically connects the first wiring pattern and the first electrode.

### CROSS-REFERENCE TO RELATED APPLICATION

This application is based upon and claims priority to Japanese Patent Application No. 2023-143597, filed on Sep. 5, 2023, the entire contents of which are incorporated herein by reference.

### FIELD

A certain aspect of the embodiment discussed herein is related to semiconductor devices.

### BACKGROUND

A semiconductor device having a semiconductor element mounted on a wiring substrate is known. To manufacture such a semiconductor device, for example, a through hole is formed in the wiring substrate, and the semiconductor element is mounted on the wiring substrate such that an electrode of the semiconductor element is exposed in the through hole. The through hole is then filled with metal plating by, for example, a semi-additive process, and the metal plating is further extended onto the wiring substrate to form a wiring layer (see, for example, Japanese Laid-open Patent Publication No. 2020-57771).

### SUMMARY

According to an embodiment, a semiconductor device includes a wiring substrate and a semiconductor element. The wiring substrate includes an insulating layer and a wiring layer. The semiconductor element includes a first electrode and is fixed to the wiring substrate with the first electrode facing the wiring substrate. The wiring layer includes a first wiring pattern on a surface of the insulating layer on the opposite side from the semiconductor element. The wiring layer further includes a first via interconnect. The first via interconnect is formed of a sintering material of metal and fills in a first through hole piercing through the first wiring pattern and the insulating layer to expose the first electrode. The first via interconnect electrically connects the first wiring pattern and the first electrode.

The object and advantages of the embodiment will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIG. 1 is a sectional view of a semiconductor device according to an embodiment;

FIGS. 2A through 2F are diagrams illustrating a process of manufacturing a semiconductor device according to the embodiment;

FIGS. 3A through 3C are diagrams illustrating a process of manufacturing a semiconductor device according to a comparative example; and

FIG. 4 is a sectional view of a semiconductor device according to a variation of the embodiment.

### DESCRIPTION OF EMBODIMENT

According to the related-art method, however, by which the through hole is filled with metal plating, which is further extended onto the wiring substrate to form a wiring layer, the upper surface of the wiring layer formed on the through hole may not be flat, and a depression (recess) may be formed in the upper surface.

For example, if a depression is formed in the upper surface of a wiring layer for external connection, a void is more likely to be generated in solder or the like in the depression when another member is bonded onto the wiring layer with the solder or the like, thus decreasing connection reliability.

According to an embodiment, it is possible to provide a semiconductor device in which the flatness of the upper surface of a wiring layer for external connection is improved.

One or more embodiments are described below with reference to the accompanying drawings. In the following, the same elements are referred to using the same reference numeral, and duplicate description thereof may be omitted.

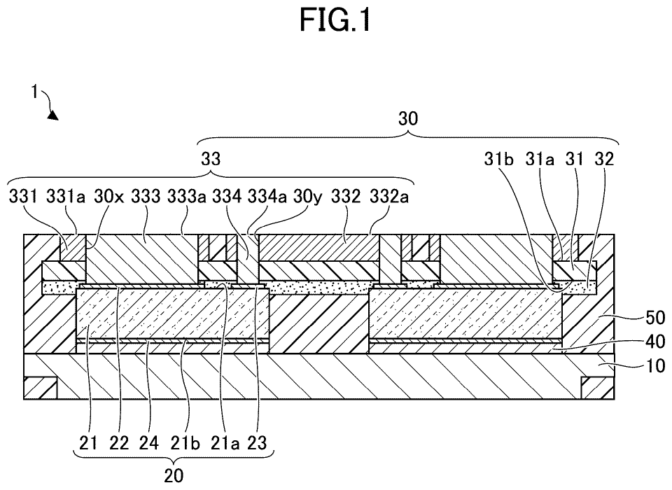

FIG. 1 is a sectional view of a semiconductor device according to an embodiment. Referring to FIG. 1, a semiconductor device 1 includes a leadframe 10, semiconductor elements 20, a wiring substrate 30, a joining member 40, and an encapsulation resin 50. The number of the semiconductor elements 20, which is two according to this embodiment, may be one or more than two. Hereinafter, the semiconductor elements 20 are collectively referred to as “semiconductor element 20” unless otherwise specified.

According to this embodiment, for convenience of description, the wiring substrate 30 side of the semiconductor device 1 is referred to “upper side”, and the leadframe 10 side of the semiconductor device 1 is referred to as “lower side.” Furthermore, with respect to each part or element of the semiconductor device 1, a surface on the wiring substrate 30 side is referred to as “upper surface” and a surface on the leadframe 10 side is referred to as “lower surface.” The semiconductor device 1, however, may be used in an inverted position or oriented at any angle. Furthermore, a plan view refers to a view of an object taken in a direction normal to the upper surface of the wiring substrate 30, and a planar shape refers to the shape of an object as viewed in a direction normal to the upper surface of the wiring substrate 30.

The leadframe 10 is formed into a flat sheet shape. The leadframe 10 may be of any planar shape and of any size. According to the example of FIG. 1, the leadframe 10 has a rectangular planar shape. Examples of materials that may be used for the leadframe 10 include copper (Cu), copper alloys, and Alloy 42. The thickness of the leadframe 10 may be, for example, 100 μm or more and 250 μm or less.

The semiconductor device 1 may include a wiring substrate in place of the leadframe 10. Examples of such a wiring substrate include a direct bonded copper (DBC) substrate and an active metal brazed (AMB) substrate.

Each semiconductor element 20 is joined to the upper surface of the leadframe 10 by the joining member 40, which is electrically conductive. Examples of materials that may be used for the joining member 40 include a sintering material of metal (a metal sintering material). Examples of metal sintering materials include a sintering material composed mainly of silver (Ag) particles (a silver sintering material) and a sintering material composed mainly of copper (Cu) particles (a copper sintering material). Examples of materials that may be used for the joining member 40 further include solder, conductive paste such as silver paste, and brazing metal. The thickness of the joining member 40 may be, for example, approximately 20 μm to approximately 60 μm.

Each semiconductor element 20 is, for example, a power semiconductor element. Each semiconductor element 20 includes a control electrode and is configured to switch in response to voltage applied to the control electrode. Examples of the semiconductor element 20 include insulated gate bipolar transistors (IGBTs), metal-oxide-semiconductor field-effect transistors (MOSFETs), and diodes.

According to this embodiment, the semiconductor element 20 is a MOSFET. The semiconductor element 20 may be of any planar shape and of any size. The semiconductor element 20 has, for example, a rectangular planar shape. The thickness of the semiconductor element 20 may be, for example, approximately 50 μm to approximately 600 μm. The coefficient of thermal expansion of the semiconductor element 20 may be, for example, approximately 3 ppm/°° C. to approximately 6 ppm/° C.

Each semiconductor element 20 includes a semiconductor substrate 21, a first electrode 22, a second electrode 23, and a third electrode 24. The second electrode 23 is the control electrode of the semiconductor element 20. The semiconductor substrate 21 is formed of, for example, silicon (Si) or silicon carbide (SiC).

Each semiconductor element 20 is provided with the first electrode 22. The semiconductor substrate 21 may be provided with the second electrode 23 on the same side as the first electrode 22. The second electrode 23 is spaced apart from the first electrode 22. The first electrode 22 and the second electrode 23 may be placed on an upper surface 21a of the semiconductor substrate 21, for example. The first electrode 22 is, for example, the source electrode of a MOSFET. The second electrode 23 is, for example, the gate electrode of a MOSFET.

Each semiconductor element 20 may be provided with the third electrode 24 on the side opposite from the first electrode 22. The third electrode 24 may be placed on a lower surface 21b of the semiconductor substrate 21. The third electrode 24 is electrically connected to the leadframe 10, which is an example of a metal member, by the joining member 40. The third electrode 24 is, for example, the drain electrode of a MOSFET.

When the semiconductor device 1 includes a wiring substrate in place of the leadframe 10, the third electrode 24 of the semiconductor substrate 21 is electrically connected to a metal member (a wiring layer or the like) on the wiring substrate by the joining member 40.

Examples of materials that may be used for the first electrode 22, the second electrode 23, and the third electrode 24 include metals such as aluminum (Al) and copper and alloys containing at least one metal selected from these metals. A surface treatment layer may be formed on the surfaces of the first electrode 22, the second electrode 23, and the third electrode 24 on an as-needed basis.

The wiring substrate 30 is placed on the semiconductor element 20. In other words, the semiconductor element 20 is fixed to the wiring substrate 30 with the first electrode 22 facing upward (toward the wiring substrate 30 side).

The wiring substrate 30 is formed into a flat sheet shape. The wiring substrate 30 may be of any planar shape and of any size. According to the example of FIG. 1, the wiring substrate 30 has a rectangular planar shape. The thickness of the wiring substrate 30 may be, for example, approximately 200 μm to approximately 400 μm. The coefficient of thermal expansion of the wiring substrate 30 may be, for example, approximately 20 ppm/° C. to approximately 25 ppm/° C. The wiring substrate 30 may be provided, for example, such that the entirety of the wiring substrate 30 is placed over the leadframe 10 in a plan view.

The wiring substrate 30 includes an insulating layer 31, a bonding layer 32, and a wiring layer 33. The insulating layer 31 is bonded to the semiconductor element 20 by the bonding layer 32. Examples of materials that may be used for the insulating layer 31 include insulating resins such as polyimide resins and polyester resins. The thickness of the insulating layer 31 may be, for example, approximately 30 μm to approximately 50 μm.

The bonding layer 32 is formed on a lower surface 31b of the insulating layer 31. The thickness of the bonding layer 32 may be, for example, approximately 20 μm to approximately 40 μm. For example, epoxy, polyimide or silicone adhesives may be used as the bonding layer 32. The bonding layer 32 may be provided in such a manner as to contain part of the semiconductor element 20, for example. In other words, the semiconductor element 20 may be partly buried in the bonding layer 32. For example, peripheral edge portions of the first electrode 22 and the second electrode 23 of the semiconductor element 20 may be buried in the bonding layer 32. Furthermore, an upper part of the side surface of the semiconductor element 20 may be covered with the bonding layer 32.

The wiring layer 33 is formed on one side of the insulating layer 31. The wiring layer 33 is a wiring layer for external connections. The wiring layer 33 includes a first wiring pattern 331 placed on an upper surface 31a of the insulating layer 31 and a first via interconnect 333. The first wiring pattern 331 is placed on the other side of the insulating layer 31 from the semiconductor element 20.

The first via interconnect 333 is placed in a first through hole 30x that successively pierces through the first wiring pattern 331, the insulating layer 31, and the bonding layer 32 to expose at least part of the upper surface of the first electrode 22. The first via interconnect 333 fills in the first through hole 30x to electrically connect the first wiring pattern 331 and the first electrode 22. An upper surface 333a of the first via interconnect 333 may be flush with, for example, an upper surface 331a of the first wiring pattern 331.

The wiring layer 33 may include a second wiring pattern 332, spaced apart from the first wiring pattern 331, on the upper surface 31a of the insulating layer 31 (on the same side as the first wiring pattern 331). Furthermore, the wiring layer 33 may include a second via interconnect 334.

The second via interconnect 334 is placed in a second through hole 30y that successively pierces through the second wiring pattern 332, the insulating layer 31, and the bonding layer 32 to expose at least part of the upper surface of the second electrode 23. The second via interconnect 334 fills in the second through hole 30y to electrically connect the second wiring pattern 332 and the second electrode 23. An upper surface 334a of the second via interconnect 334 may be flush with, for example, an upper surface 332a of the second wiring pattern 332.

The first wiring pattern 331 and the first via interconnect 333 connect the first electrodes 22 of the semiconductor elements 20. The first electrodes 22 of the semiconductor elements 20 may be connected by, for example, the first wiring pattern 331 that does not appear in the section of FIG. 1. The second wiring pattern 332 and the second via interconnect 334 connect the second electrodes 23 of the semiconductor elements 20. The leadframe 10 connects the third electrodes 24 of the semiconductor elements 20. Thus, according to the example of FIG. 1, the semiconductor elements 20 are interconnected in parallel.

Examples of materials that may be used for the first wiring pattern 331 and the second wiring pattern 332 include copper and copper alloys. A surface treatment layer may be formed on the upper surface of the wiring layer 33 on an as-needed basis. The coefficient of thermal expansion of the wiring layer 33 may be, for example, approximately 15 ppm/° C. to approximately 18 ppm/° C. The thickness of the wiring layer 33 may be, for example, approximately 50 μm to approximately 200 μm.

The first via interconnect 333 and the second via interconnect 334 may be formed of, for example, a metal sintering material. Examples of metal sintering materials that may be used include a sintering material composed mainly of silver (Ag) particles (a silver sintering material) and a sintering material composed mainly of copper (Cu) particles (a copper sintering material). The first via interconnect 333 and the second via interconnect 334 are circular in a plan view, for example. The first via interconnect 333 and the second via interconnect 334 may have their respective diameters appropriately determined according to the size of electrodes to which to connect.

The encapsulation resin 50 encapsulates the semiconductor element 20 interposed between the leadframe 10 and the wiring substrate 30. Examples of materials that may be used for the encapsulation resin 50 include a non-photosensitive insulating resin composed mainly of a thermosetting resin. Specific examples of materials that may be used for the encapsulation resin 50 include insulating resins such as epoxy resins and polyimide resins and resin materials formed of such resins mixed with filler such as alumina. For example, a mold resin may be used as the encapsulation resin 50. The coefficient of thermal expansion of the encapsulation resin 50 may be, for example, approximately 5 ppm/° C. to approximately 18 ppm/° C.

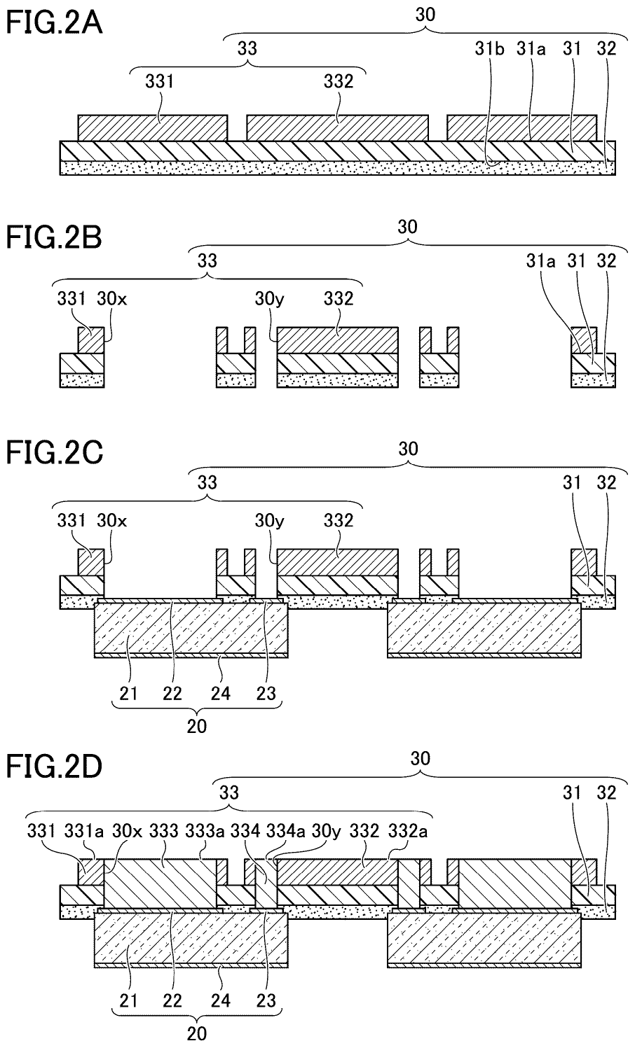

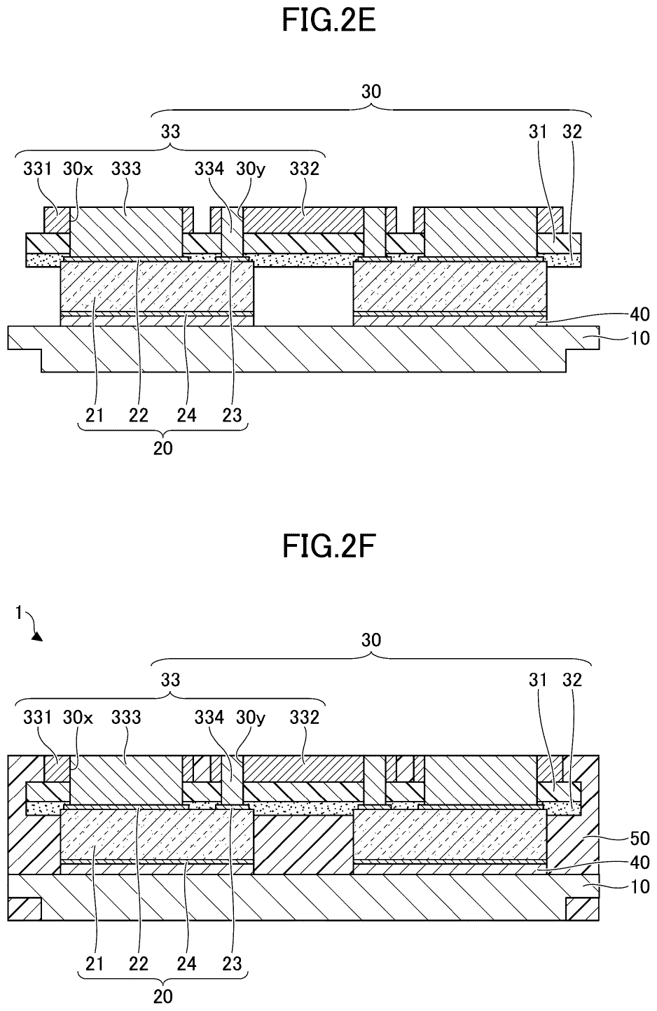

Next, a method of manufacturing the semiconductor device 1 is described. For convenience of description, parts or portions to eventually become constituent elements of the semiconductor device 1 are referred to using the reference numerals of the constituent elements. FIGS. 2A through 2F are diagrams illustrating a process of manufacturing a semiconductor device according to this embodiment.

First, in the process illustrated in FIG. 2A, a

wiring substrate including an insulating layer and a first wiring pattern placed on the insulating layer is prepared. According to this embodiment, by way of example, the wiring substrate 30 including the insulating layer 31, the bonding layer 32, and the wiring layer 33 (the first wiring pattern 331 and the second wiring pattern 332) is prepared. Specifically, for example, a member in which the wiring layer 33 of a predetermined pattern is preformed on the upper surface 31a of the insulating layer 31 is purchased, and the bonding layer 32 is formed on the lower surface 31b of the insulating layer 31. Instead of purchasing such a member, the wiring layer 33 may be formed on the upper surface 31a of the insulating layer 31, using one or more of various wiring formation processes such as a subtractive process and a semi-additive process.

Next, in the process illustrated in FIG. 2B, the first through hole 30x that successively pierces through the first wiring pattern 331, the insulating layer 31, and the bonding layer 32 is formed. Furthermore, the second through hole 30y that successively pierces through the second wiring pattern 332, the insulating layer 31, and the bonding layer 32 is formed. The first through hole 30x and the second through hole 30y may be formed by, for example, pressing. The first through hole 30x and the second through hole 30y may also be formed by, for example, a combination of etching and laser processing. In this case, first, the first wiring pattern 331 is removed by etching to expose the upper surface 31a of the insulating layer 31 where the first through hole 30x is to be formed, and the second wiring pattern 332 is removed by etching to expose the upper surface 31a of the insulating layer 31 where the second through hole 30y is to be formed. Thereafter, laser light is emitted onto the upper surface 31a of the insulating layer 31 exposed by the etching to form the first through hole 30x and the second through hole 30y through the insulating layer 31.

Next, in the process illustrated in FIG. 2C, the semiconductor element 20 including the first electrode 22, the second electrode 23, and the third electrode 24 is prepared. The semiconductor element 20 is fixed to the wiring substrate 30 by the bonding layer 32 such that the first electrode 22 is exposed in the first through hole 30x and the second electrode 23 is exposed in the second through hole 30y on the side of the insulating layer 31 of the wiring substrate 30 opposite from the first wiring pattern 331.

Next, in the process illustrated in FIG. 2D, the first through hole 30x and the second through hole 30y are filled with a metal sintering material in paste form to be sintered into the first via interconnect 333 and the second via interconnect 334. Specifically, for example, a sintering material in paste form (sintering paste) may be applied into the first through hole 30x and the second through hole 30y by printing or dispensing. Examples of sintering paste that may be used include silver sintering paste in which silver particles are dispersed in an organic solvent. Examples of printing that may be used include screen printing and stencil printing.

Thereafter, the structure illustrated in FIG. 2D is vertically held and pressed between parallel flat plates, so that the upper surface 333a of the first via interconnect 333 in paste form can be flush with the upper surface 331a of the first wiring pattern 331 and the upper surface 334a of the second via interconnect 334 in paste form can be flush with the upper surface 332a of the second wiring pattern 332.

Next, in the process illustrated in FIG. 2E, the leadframe 10 and the semiconductor element 20 are joined. First, the joining member 40 is formed at a position where the semiconductor element 20 is to be mounted on the upper surface of the leadframe 10. The joining member 40 may be formed by, for example, applying a sintering material in paste form (sintering paste) by printing or dispensing. Examples of sintering paste that may be used include silver sintering paste in which silver particles are dispersed in an organic solvent. Examples of printing that may be used include screen printing and stencil printing.

Next, the semiconductor element 20 fixed to the wiring substrate 30 is placed on the upper surface of each joining member 40. Specifically, the third electrode 24 at the lower surface of the semiconductor element 20 is placed on the joining member 40 in paste form on the leadframe 10, which is a metal member. Next, the first via interconnect 333 and the second via interconnect 334 in paste form and the joining member 40 in paste form are sintered to form the first via interconnect 333, the second via interconnect 334, and the joining member 40.

As a result, the first wiring pattern 331, the first via interconnect 333, the second wiring pattern 332, and the second via interconnect 334 form the wiring layer 33 for external connections. Furthermore, the first via interconnect 333 electrically connects the first wiring pattern 331 and the first electrode 22. In additions, the second via interconnect 334 electrically connects the second wiring pattern 332 and the second electrode 23. Moreover, the joining member 40 electrically connects the third electrode 24 and the leadframe 10.

Thus, the manufacturing process may be shortened by simultaneously performing the sintering of the first via interconnect 333 and the second via interconnect 334 in paste form and the sintering of the joining member 40 in paste form.

The sintering of the first via interconnect 333 and the second via interconnect 334 in paste form and the sintering of the joining member 40 in paste form may be performed in separate processes. That is, the first via interconnect 333 and the second via interconnect 334 in paste form may be sintered in the process illustrated in FIG. 2D and the joining member 40 in paste form may be sintered in the process illustrated in FIG. 2E. Furthermore, in the case of sintering the first via interconnect 333 and the second via interconnect 334 in paste form in the process illustrated in FIG. 2D, the structure illustrated in FIG. 2D may be shipped as a semiconductor device product.

Next, in the process illustrated in FIG. 2F, the encapsulation resin 50, which encapsulates the semiconductor element 20 interposed between the leadframe 10 and the wiring substrate 30, is formed. For example, the encapsulation resin 50 may be formed to expose the upper surface of the wiring layer 33 and the lower surface of the leadframe 10 while covering the other area. The encapsulation resin 50 may be formed using a process such as transfer molding, compression molding or injection molding. As a result of the above-described process, the semiconductor device 1 is completed.

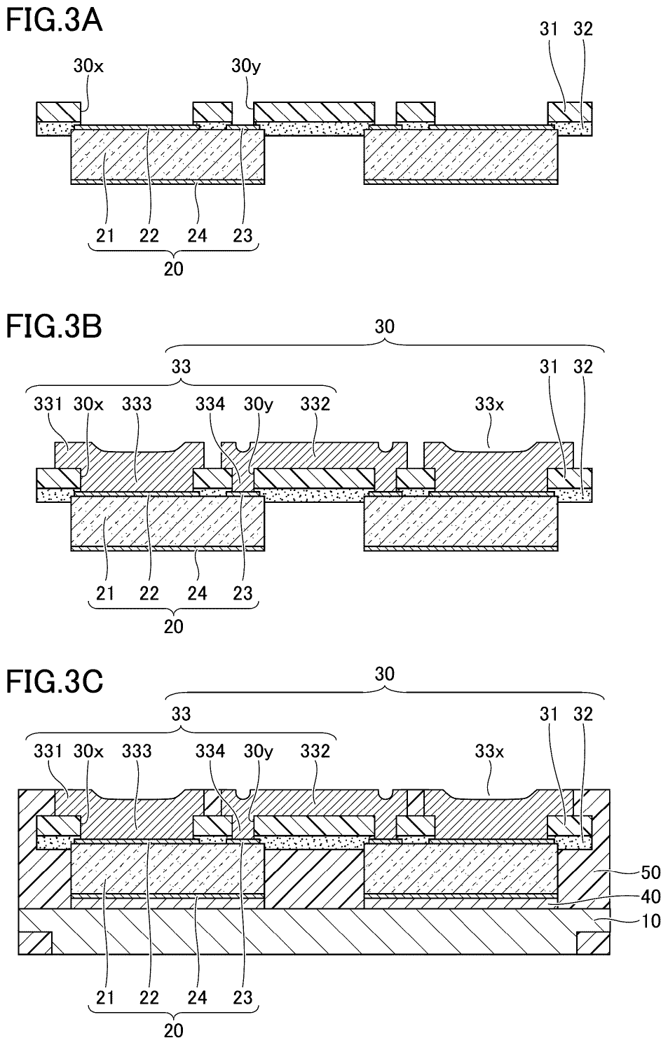

FIGS. 3A through 3C are diagrams illustrating a method of manufacturing a semiconductor device according to a comparative example. First, in the process illustrated in FIG. 3A, a laminate of the insulating layer 31 and the bonding layer 32 is prepared, and the first through hole 30x and the second through hole 30y that pierce through the insulating layer 31 and the bonding layer 32 are formed. Then, the semiconductor element 20 is bonded to the lower surface of the bonding layer 32. At this point, the semiconductor element 20 is positioned so that at least part of the upper surface of the first electrode 22 is exposed in the first through hole 30x and at least part of the upper surface of the second electrode 23 is exposed in the second through hole 30y.

Next, in the process illustrated in FIG. 3B, the first wiring pattern 331, the first via interconnect 333, the second wiring pattern 332, and the second via interconnect 334 are formed. Specifically, for example, a seed layer is formed on the surface of the insulating layer 31 including the inner wall surfaces of the first through hole 30x and the second through hole 30y and on the surface of the first electrode 22 and the surface of the second electrode 23 that are exposed in the first through hole 30x and the second through hole 30y, respectively, by electroless plating or sputtering. The seed layer is, for example, a copper layer. A laminate film in which a copper layer is stacked on a titanium layer may be used as the seed layer.

Next, a plating resist pattern having openings

that match the shape of the first wiring pattern 331 and the shape of the second wiring pattern 332 is formed on the seed layer. Next, an electroplating layer is deposited on the seed layer exposed in the openings of the plating resist pattern by copper electroplating that supplies power from the seed layer. Next, the plating resist pattern is removed using a resist remover for removing plating resist. Next, etching is performed using the electroplating layer as a mask to remove the seed layer exposed from the electroplating layer.

As a result, the first wiring pattern 331, the second wiring pattern 332, the first via interconnect 333, and the second via interconnect 334 having a structure in which the electroplating layer is stacked on the seed layer are completed. The first wiring pattern 331 and the first via interconnect 333 are formed as a one-piece structure and the second wiring pattern 332 and the second via interconnect 334 are formed as a one-piece structure. At this point, it is difficult to sufficiently deposit the first via interconnect 333 and the second via interconnect 334 by electroplating. Therefore, a recess 33x is formed in each of the upper surface of the first wiring pattern 331 positioned above the first through hole 30x and the upper surface of the second wiring pattern 332 positioned above the second through hole 30y. Thereafter, in the process illustrated in FIG. 3C, the semiconductor device according to the comparative example is completed.

The formation of the recess 33x increases the possibility of generation of a void in solder inside the recess 33x when a member such as a bus bar is soldered to the first wiring pattern 331 and the second wiring pattern 332, for example. The generation of a void in the solder reduces the reliability of joining between the first and second wiring patterns 331 and 332 and a member joined to the first and second wiring patterns 331 and 332.

In contrast, according to the semiconductor device 1, the first via interconnect 333 and the second via interconnect 334 are not formed by electroplating of copper or the like, but are formed by printing or the like using a sintering material in paste form and sintering. According to this process, no recess is formed in the upper surface 333a of the first via interconnect 333 or the upper surface 334a of the second via interconnect 334. Therefore, it is possible to improve the flatness of the upper surface of the wiring layer 33 for external connections.

Therefore, a void is less likely to be generated in solder when a member such as a bus bar is soldered to the first wiring pattern 331 and the first via interconnect 333 or the second wiring pattern 332 and the second via interconnect 334. This makes it possible to improve the reliability of joining between the wiring layer 33 and a member joined to the wiring layer 33.

Furthermore, the first via interconnect 333 and the second via interconnect 334 formed of a sintering material are directly connected to the semiconductor element 20, which is a heating element. A via interconnect formed of a sintering material, which has a higher thermal conductivity than a wiring pattern and a via interconnect formed of copper, can increase the heat dissipation of the semiconductor device 1. The thermal conductivity of copper is approximately 398 W/m·K, and the thermal conductivity of a silver sintering material is approximately 420 W/m·K.

Furthermore, the first via interconnect 333 and the second via interconnect 334 formed of a sintering material, which has a lower elasticity than copper, can reduce stress compared with a via interconnect formed of copper. For example, while the elasticity of copper is approximately 60 GPa to approximately 150 GPa, the elasticity of a silver sintering material is approximately, 10 GPa to approximately, 90 GPa.

As a variation of the embodiment, an example

where multiple via interconnects are connected to a single electrode is illustrated. In the description of the variation, a description of the same elements as those of the above-described embodiment may be omitted.

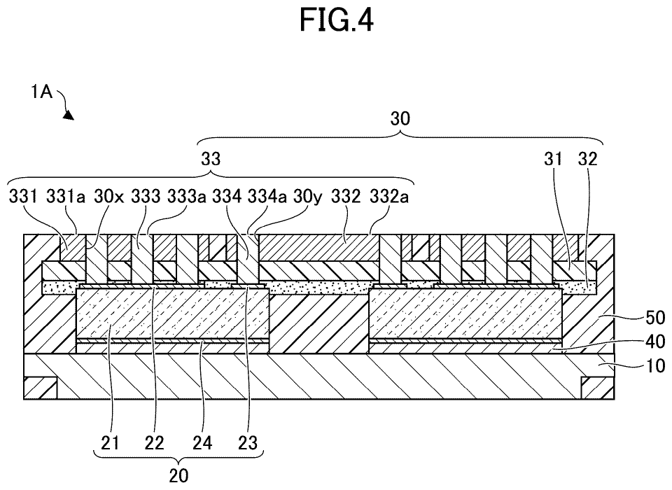

FIG. 4 is a sectional view of a semiconductor

device according to the variation. Referring to FIG. 4, a semiconductor device 1A is different from the semiconductor device 1 in that the multiple first via interconnects 333 are connected to the single first electrode 22.

The first via interconnects 333 are equal in volume. The first via interconnects 333 and the second via interconnect 334 are equal in volume. That is, each first through hole 30x and the second through hole 30y are equal in volume. Here, being equal in volume means having substantially the same volume and allows manufacturing variations.

As illustrated in FIG. 4, the first via interconnects 333 and the second via interconnect 334 each have a substantially constant width irrespective of a position in the thickness direction in a sectional view. That is, the cross-sectional area of each of the first via interconnects 333 and the second via inter connect 334 (for example, the area of a cross section in a plane parallel to its upper surface) remains the same (unchanged) irrespective of a position in the thickness direction.

According to the semiconductor device 1A, the same as in the semiconductor device 1, the first via interconnects 333 and the second via interconnect 334 are not formed by electroplating of copper or the like, but are formed by printing or the like using a sintering material in paste form and sintering. As a result, the same effects as produced by the semiconductor device 1 are produced.

Furthermore, according to the semiconductor device 1A, the first through holes 30x and the second through hole 30y are equal in volume. Therefore, the degree of filling is less likely to vary when the first through holes 30x and the second through hole 30y are filled with a sintering material in paste form. Therefore, the upper surfaces of the first via interconnects 333 and the second via interconnect 334 can be easily flattened.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

Various aspects of the subject-matter described herein may be set out non-exhaustively in the following numbered clauses:
1. A method of manufacturing a semiconductor device, the method including:
preparing a wiring substrate, the wiring substrate including an insulating layer and a first wiring pattern on the insulating layer;
forming a first through hole piercing through the first wiring pattern and the insulating layer;
preparing a semiconductor element including a first electrode and fixing the semiconductor element to the wiring substrate on an opposite side of the insulating layer from the first wiring pattern such that the first electrode is exposed in the first through hole;
filling the first through hole with a first sintering material of metal in paste form; and
sintering the first sintering material to form a first via interconnect to form a wiring layer of the first wiring pattern and the first via interconnect.
2. The method of clause 1, further including:
placing a second electrode of the semiconductor element on a metal member with a second sintering material of metal in paste form being interposed between the second electrode and the metal member, the second electrode being on the opposite side of the semiconductor element from the first electrode; and
sintering the second sintering material to form a joining member to electrically connect the second electrode and the metal member by the joining member,
wherein the first sintering material and the second sintering material are simultaneously sintered.

What is claimed is:

1. A semiconductor device comprising:
a wiring substrate including an insulating layer and a wiring layer; and
a semiconductor element including a first electrode, the semiconductor element being fixed to the wiring substrate with the first electrode facing the wiring substrate,
wherein the wiring layer includes
a first wiring pattern on a surface of the insulating layer on an opposite side from the semiconductor element; and
a first via interconnect formed of a sintering material of metal and filling in a first through hole piercing through the first wiring pattern and the insulating layer to expose the first electrode, the first via interconnect electrically connecting the first wiring pattern and the first electrode.

2. The semiconductor device as claimed in claim 1, wherein a surface of the first wiring pattern facing away from the insulating layer is flush with a surface of the first via interconnect facing away from the semiconductor element.

3. The semiconductor device as claimed in claim 1, wherein
the semiconductor element further includes a second electrode on the same side as the first electrode, the second electrode being spaced apart from the first electrode,
the wiring layer further includes
a second wiring pattern on the surface of the insulating layer, the second wiring pattern being spaced apart from the first wiring pattern; and
a second via interconnect formed of the sintering material and filling in a second through hole piercing through the second wiring pattern and the insulating layer to expose the second electrode, the second via interconnect electrically connecting the second wiring pattern and the second electrode.

4. The semiconductor device as claimed in claim 3, wherein a surface of the second wiring pattern facing away from the insulating layer is flush with a surface of the second via interconnect facing away from the semiconductor element.

5. The semiconductor device as claimed in claim 3, wherein
the first via interconnect includes a plurality of via interconnects connected to the first electrode, and
the plurality of via interconnects and the second via interconnect are equal in volume.

6. The semiconductor device as claimed in claim 1, wherein a thermal conductivity of the sintering material is higher than a thermal conductivity of the first wiring pattern.

7. The semiconductor device as claimed in claim 1, wherein
the semiconductor element further includes a third electrode on an opposite side from the first electrode, and
the third electrode is electrically connected to a metal member via a joining member.

8. The semiconductor device as claimed in claim 7, wherein the joining member is formed of a sintering material of metal.

9. The semiconductor device as claimed in claim 1, wherein the wiring substrate further includes a bonding layer bonding the insulating layer to the semiconductor element.

10. The semiconductor device as claimed in claim 1, wherein the sintering material is a silver sintering material or a copper sintering material.

11. The semiconductor device as claimed in claim 1, wherein the first wiring pattern is formed of copper or a copper alloy.

12. The semiconductor device as claimed in claim 1, wherein an elasticity of the sintering material is lower than an elasticity of the first wiring pattern.

13. The semiconductor device as claimed in claim 1, further comprising:
a metal member;
a joining member joining the metal member to the semiconductor element; and
an encapsulation resin encapsulating the semiconductor element interposed between the metal member and the wiring substrate.
